(19) United States
(12) Patent Application Publication
(10) Pub. No.: US 2011/0035063 A1
(43) Pub. Date: Feb. 10, 2011

(54) Water Management System

(76) Inventor: Saju Anthony Palayur, San Diego, CA (US)

Correspondence Address: GEORGE S. LEVY, 3980 DEL MAR MEADOWS, SAN DIEGO, CA, 92130, US

(21) Appl. No.: 12/904,682

(22) Filed: Oct. 14, 2010

Related U.S. Application Data
(60) Provisional application No. 61/346,267, filed on May 19, 2010.
(60) Provisional application No. 61/253,199, filed on Oct. 20, 2009.

(51) Int. Cl. G05D 7/06; G06F 17/00; G01F 1/00; G01R 21/00; G06F 19/00; G08B 21/00

(52) U.S. Cl. 700/283; 705/413; 700/282; 702/45; 702/60; 340/626

(57) ABSTRACT

This invention is a water consumption monitoring and control system comprised of a base unit, itself comprising a display and a data entry device, a microprocessor, a communication link to water meters, pressure sensors, temperature sensors, flush toilet vibration sensors and shut-off valves. In addition the base unit has access to the Internet and can access a server which holds a database of water conservation information. This database includes watering advisories from the local government, and weather information from the weather office. The server runs an algorithm and generates control data which is sent to the base unit.

### FIELD OF THE INVENTION

This invention claims the benefit of U.S. Provisional Applications No. 61/346,267, titled “Intelligent data logging, analysis system and/or subscription service for single and multi-site synchronous data, not limited to wind, solar analysis and water conservation applications” filed on May 19, 2010, and U.S. Provisional Applications No. 61/253,199 titled “Intelligent data logging and analysis system for single and multi-site synchronous data, not limited to wind and solar analysis applications and subscription service” filed on Oct. 20, 2009. Both of these applications are hereby incorporated by reference. Applicant claims priority pursuant to 35 U.S.C. Par 119(e)(i). The present invention relates to the monitoring and control of water consumption.

### BACKGROUND

Freshwater is vital to health and to the economy, and reliable access to it is becoming increasingly important as the human population on Earth increases. Yet its availability is limited. Conservation is an important issue and therefore, water management tools are important, especially those tools that provide average households with the means for managing their own water consumption.

Many devices exist for monitoring and controlling water usage, but they provide limited functionality. For example water meters exist that allow consumers to measure their own water usage. These devices however have no time resolution or past history records. Users cannot tell exactly when water is being used and by whom. Water thermometers exist that allow consumers to measure the temperature of their hot water and indirectly the amount of energy they use for heating water. These thermometers, however, are not connected to a central control system that monitors energy usage. Water valves exist that allow users to shut off water flow but these devices are not connected to a central management system that can control their open or close status. Flood alarms exist but they are not integrated with a central water management system capable of shutting off water in case of a flood. Water pressure measurement systems exist but they are not integrated with a central management system capable of displaying pressure and of shutting off valves either in case of overpressure that could damage sprinklers or appliances, or in case of underpressure indicative of pipe breakage. Weather monitoring systems exist but are not integrated with a central water management system capable, for example of regulating lawn irrigation. Billing systems exist but they are not integrated with a central water management system. Furthermore these devices are limited in their capabilities to communicate with consumers. The Rain Bird Company is marketing a smart controller that can be used to control sprinkler time based on weather data from public weather server data. But this controller does not use water authority mandates that are put in place sometimes during droughts to change watering time into their schedules and is not integrated into a comprehensive water management system.

Current water monitoring systems only send the cumulative water flow measurement in the form of a count, every few hours. This relatively long time interval makes water consumption monitoring impossible to perform in real time.

None of the water meters have an integrated shut off value that can be activated remotely. The decision is made at the water companies to shut off water distribution.

None of the prior art offers the entertainment value of this invention. Further features, aspects, and advantages of the present invention over the prior art will be more fully understood when considered with respect to the following detailed description claims and accompanying drawings.

### BRIEF DESCRIPTION OF THE DRAWINGS

FIG. 1 illustrates the whole system, showing the base unit in communication with water sensors and actuators, and through the Internet, with a server, user computers, mobile devices, water companies and weather information services.

FIG. 2 provides a block diagram of the base unit which includes a microprocessor, a display, a data entry device, and a communication system.

FIG. 3 represents the functional flow diagram of the base unit.

FIG. 4 illustrates the power up sequence for the base unit.

FIG. 5 shows the functional block diagram for the sensor monitoring operation of the base unit.

FIG. 6 is a functional flow diagram of the decision process and quota utilization for the base unit.

FIG. 7 illustrates the functional flow diagram for outputting messages and alarms.

FIG. 8 shows the functional flow diagram for the operation of the water meter sensor.

FIG. 9 illustrates the functional flow diagram for the operation of the water temperature sensor.

FIG. 10 represents the functional flow diagram of the water pressure sensor.

FIG. 11 illustrates the functional flow diagram for the toilet flush sensor.

FIG. 12 shows the functional flow diagram for the floor moisture sensor used to detect floods.

FIG. 13 provides the flow diagram of the operation of a rain sensor.

FIG. 14 illustrates the functional flow diagram for the shut off valve actuator.

FIG. 15 shows the communication of the Internet server with each base unit.

FIG. 16 illustrates how the Internet server collects cost data from a water utility company and updates the base units according to this data.

FIG. 17 shows how the Internet server updates the user profile, water meter profile, and utility rates and water rates.

FIG. 18 illustrates how the Internet server collects mandated watering times from a water utility company and updates the base units and sprinklers according to this data

FIG. 19 illustrates how the Internet server collects weather data and updates the base units and sprinklers according to this data.

FIG. 20 illustrates how the fluctuating magnetic field near a water meter can be used to extract water usage information.

FIG. 21 shows how an optical technique can be used to read a water meter and extract water usage information.

### SUMMARY OF THE INVENTION

This invention is a water consumption monitoring and control system that allows a user to monitor and control water consumption. It is comprised of a base unit which itself comprises
a) a display and a data entry device;
b) a microprocessor
c) a communication link connected to a water meter, through which water usage information is transmitted to the base unit.
d) a second communication link to the Internet through which a user can monitor and control his water usage. The water usage can be converted to a dollar amount for the benefit of the user.

The water consumption monitoring and control system is also connected to pressure sensors. The received pressure information is compared to pre-entered criteria. An alarm is generated if the pressure information does not conform to the pre-entered criteria. For example, a low pressure may indicate breakage or leak in a water pipe. This alarm is used to generate a message over the Internet in the form of email, tweet or text. Text messaging could use, for example, the Short Message Service (SMS) protocol.

The water consumption monitoring and control system is also connected to water shut-off valves. The received pressure information is compared with pre-entered criteria. A shut-off signal is generated if the pressure information does not conform to the pre-entered criteria. This shut-off signal is sent to the shut-off valves.

Communication is established over the Internet with the local water utility company. Water usage and pressure information is sent to the company which compares this data against pre-set usage and pressure criteria and sends shut-off command signals to the base unit if the information does not conform to the pre-set usage and pressure criteria. This shut off signal is forwarded to the shut-off valves. Possible reasons for shutting off the water supply is that the utility company may determine that the water is unsafe to drink or that customers have not paid their bills.

Communication is established over the Internet between the base unit and an Internet server. Water usage and pressure data are sent to the server which evaluates this information and returns usage control information to the base unit.

Water schedule advisories are received over the Internet from the local government water department. This data is used by the Internet server to generate government advisory control information which is sent to the base unit.

Weather information is received over the Internet from the weather office. This data is used by the Internet server to generate weather advisory control information which is sent to the base unit.

The base unit is also connected to, and can control the operation of, a sprinkler system.

Water temperature information is also transmitted to the base unit and used to calculate the energy used in heating water.

Floor moisture sensors that generate information regarding the absence or presence of a flood are also linked to the base unit. In the presence of a flood, an alarm is generated and an Internet message is sent to the user.

The base unit is also connected to vibration sensors configured to detect the vibrations produced by flushing toilets. Malfunctioning toilets which may take too long to fill can thus be identified.

The base unit can also be connected to several water meters, each water meter located in a different housing or commercial unit, thereby allowing the user (for example the landlord) to monitor the tenant's usage. Similarly the base unit can monitor water usage at different points within a single house.

The microprocessor in the base unit can record water usage as well as pressure and temperature information over a period of time and use this historical information to detect water wastage and to detect leaks and pipe breakage.

The base unit can also provide to the user the information regarding the water consumption of his neighbors (or user defined groups anywhere in the world like families, brother and sisters, college campus or special interest groups) and his rank in water usage, thereby stimulating water conservation through competitive thinking.

### DETAILED DESCRIPTION

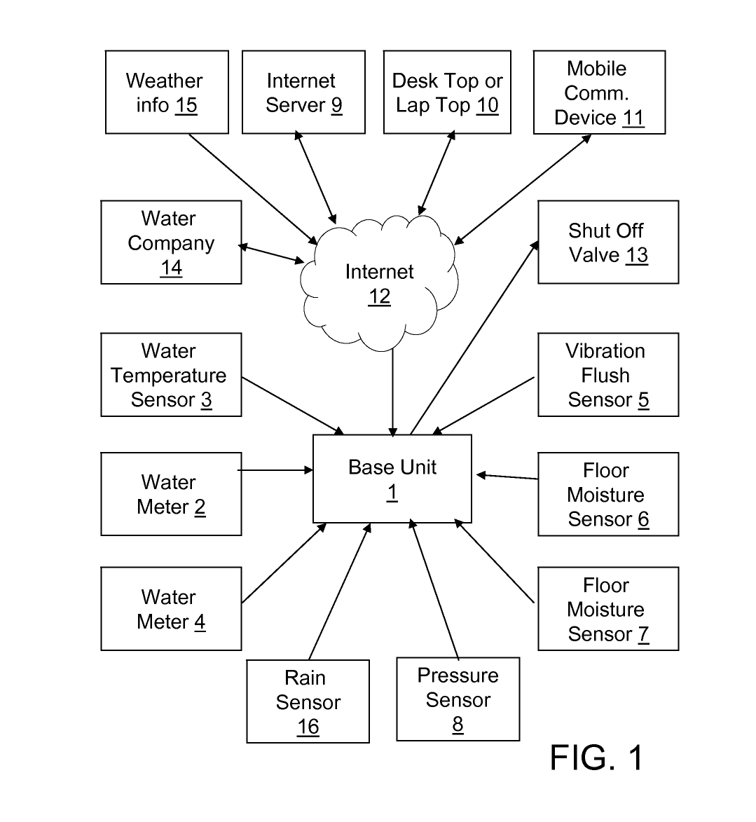

The system block diagram of the invention is shown in FIG. 1. It comprises the following components:
a) A display/control panel called the base unit.1
b) A series of sensors including water temperature sensors 3, water pressure sensors 8, floor moisture sensors 7, vibration flush sensors 5, water meters 2, 4, rain sensors/gauge 16.
c) A series of actuators, such as shut off valves 13.
d) Communication links to several entities located on the Web in particular a server 9, a utility company 14 (water company), a weather information service 15 and user mobile communication devices (e.g., cell phones)
e) An internet server 9
f) Desk top or lap top computers 10
g) User mobile communication devices 11

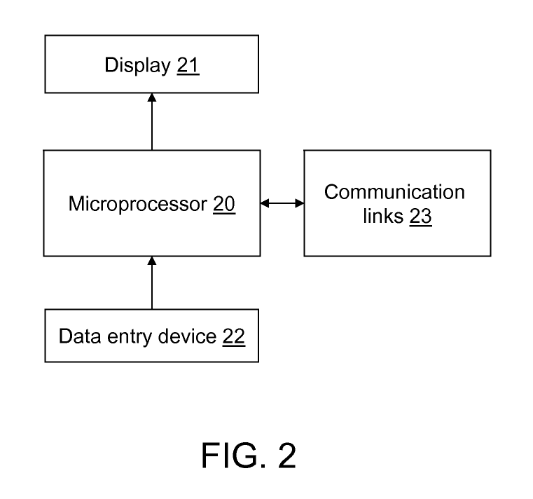

The base unit 1 is configured to monitor and control water consumption. The block diagram of the base unit is shown in FIG. 2. It comprises a microcontroller 21, a display 21, a data entry device 22 and at least one communication link 23.

The communication links 23 can include communication from the sensors to the actuators. This communication can be implemented by means of a wire or wirelessly for example, by means of ISM band transceivers, Zigbee or WiFi. The communication also includes access to the Internet, either wirelessly, or by means of a wired ethernet.

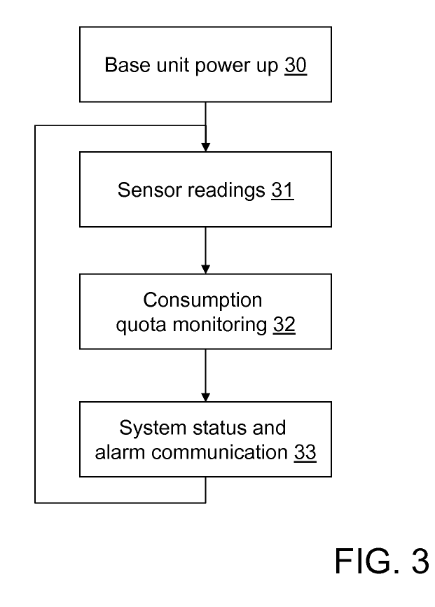

The overall operation of the microcontroller 20 is illustrated in the flow diagrams provided in FIG. 3. It includes
a) a power up sequence 30,
b) inputting sensor data 31,
c) quota evaluation and monitoring 32, and
d) outputting system status and alarm data 33.

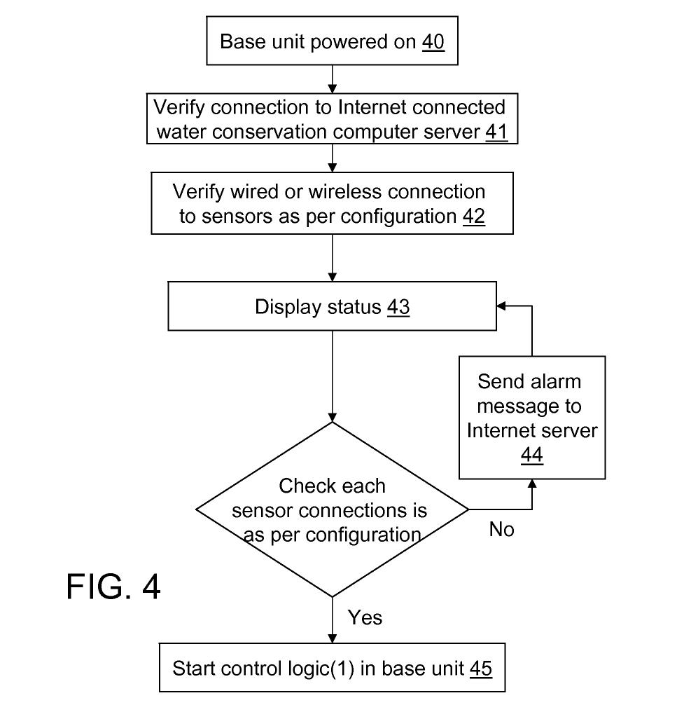

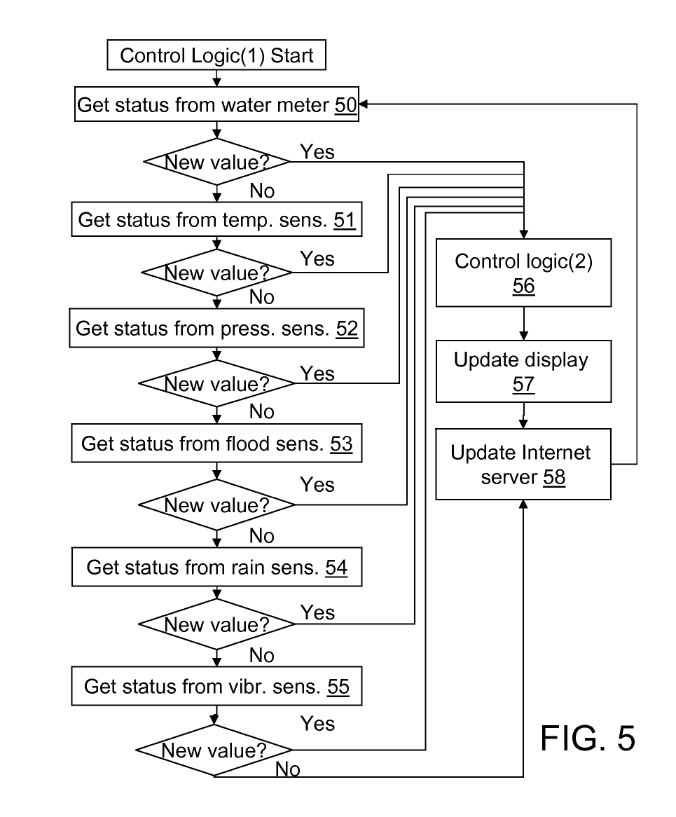

The power up sequence 30 is illustrated in detail in FIG. 4. It includes the following:
a) powering up 40 the base unit 1,
b) verifying 41 that the connection to the water conservation server on the Internet is working,
c) verifying 42 that the wired or wireless connections to the sensors and actuators are operational,
d) displaying 43 the status of the system,
e) sending an alarm 44 in case of system failure,
f) starting the Control Logic (1) software 45 which inputs sensor data and monitors sensor operation. This software is shown in greater detail in FIG. 5.

Inputting software data and monitoring software operation performed by Control Logic (1) 45 is shown in detail in FIG. 5. Data is received from flow sensors (water meters) 50, temperature sensors 51, pressure sensors 52, flood sensors 53, rain sensors/gauge 54, and vibration sensors 55. If this information has changed, the Control Logic (2) software 56 is invoked, the display is updated 57, and the Internet server is also updated 58.

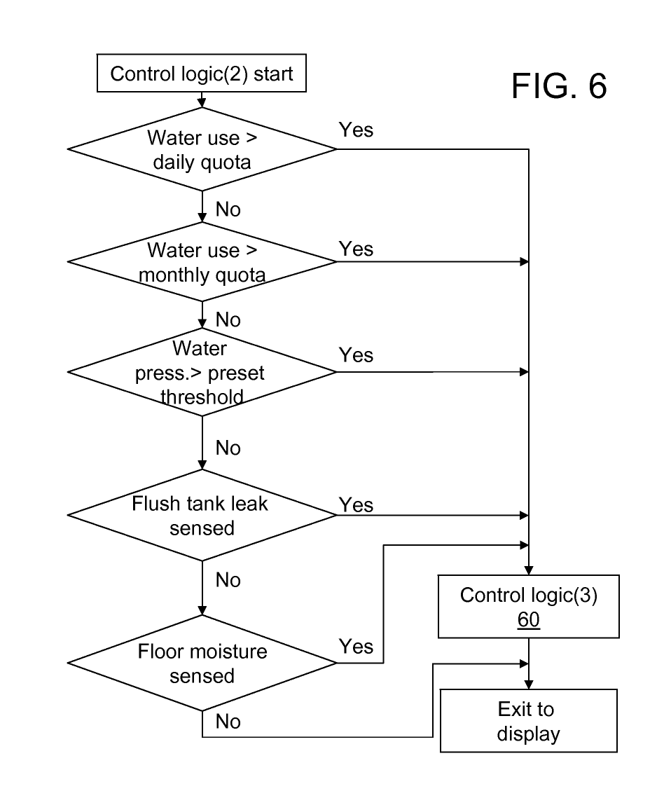

The Control Logic (2) software is illustrated in detail in FIG. 6. The collected sensor data is compared against a set of quotas, limits or decision paradigms entered by the user or received from the server through the Internet. For example, a quota could be a daily threshold, or a monthly allowance for water usage, not to be exceeded. A decision paradigm could be a low level flow over a long period of time, which may indicate a leak in a faucet, toilet or other appliance. A decision paradigm could also be an overall low water consumption level worthy of signaling to the users as a sign that they are saving water. If a quota is exceeded or if a decision paradigm is triggered, the next step of the process as embodied in Control Logic (3) 60 is invoked.

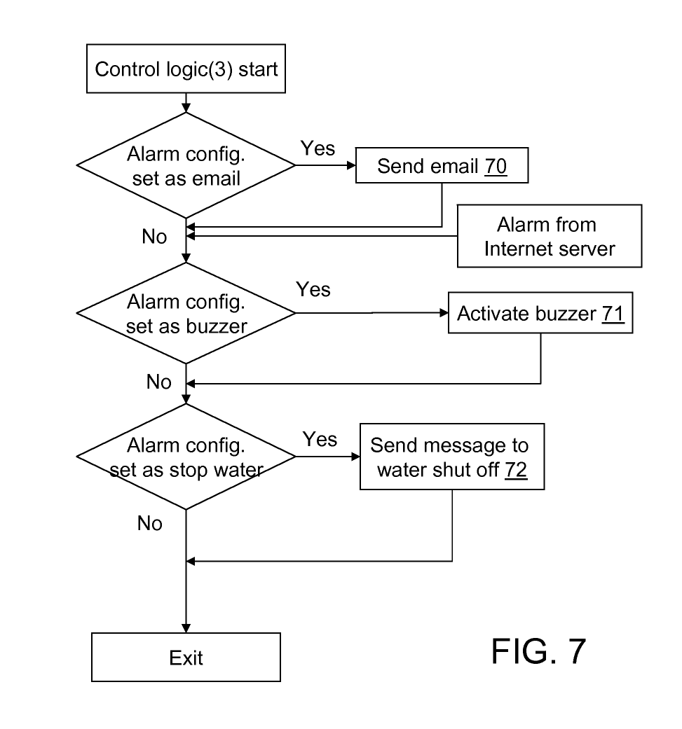

Control Logic (3) is shown in detail in FIG. 7. Depending on the alarm configuration as set up by the user different actions are undertaken. For example, an email, SMS or twitter messages can be sent 70 over the Internet, a buzzer can be activated 71 or a water valve can be shut off 72.

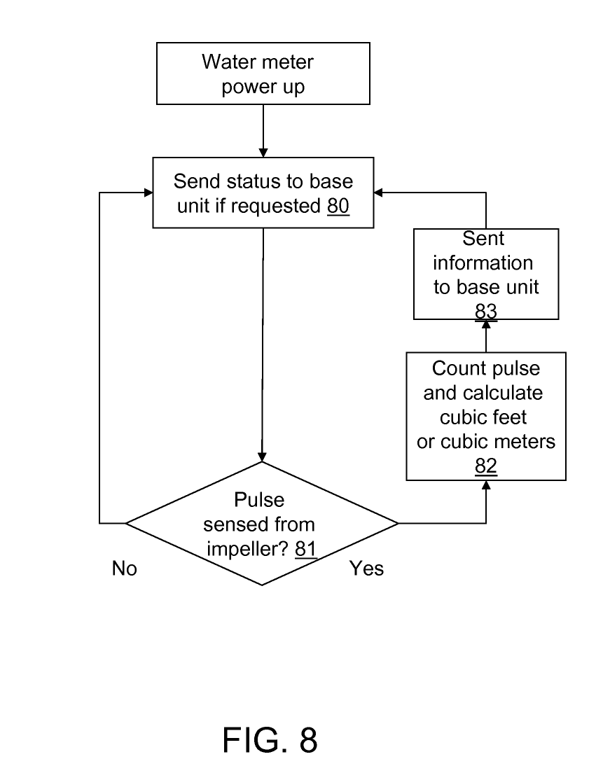

Each component of the system, peripheral to the base unit 1 is equipped with the link necessary to communicate with the base unit 1. For example, the operation of the water meter 2, 4 is shown in FIG. 8. Upon powering up, the water meter performs the following cycle.
a) It sends status information to the base unit 1 if requested 80.
b) It measures the water flow 81.
c) It calculates the flow from count pulse and converts this flow to cubic feet or cubic meters 82. Then it sends 83 this information to the base unit.

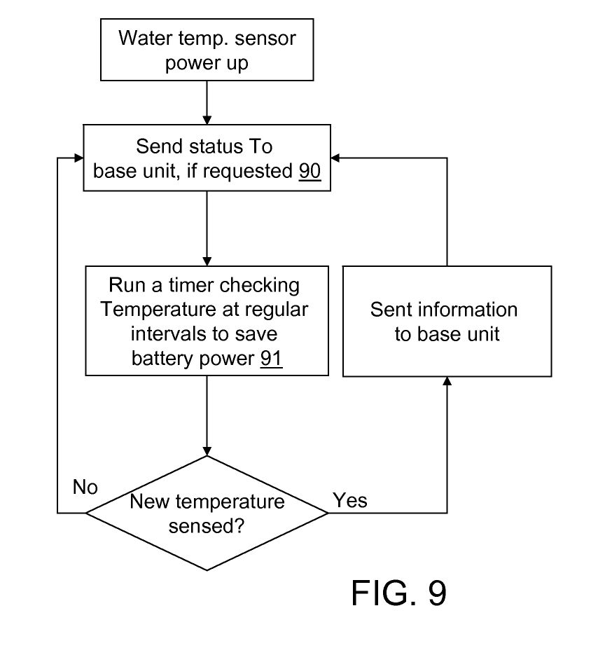

Another sensor of interest is the water temperature sensor 3 which indirectly indicates the amount of energy spent in heating water. The flow diagram for this sensor is shown in FIG. 9. Upon powering up, the sensor status is sent to the base unit 1 if requested 90. To save power, the temperature is sampled 91 at time intervals as instructed by the base unit 1. If a new temperature is detected this information is sent to the base unit 1.

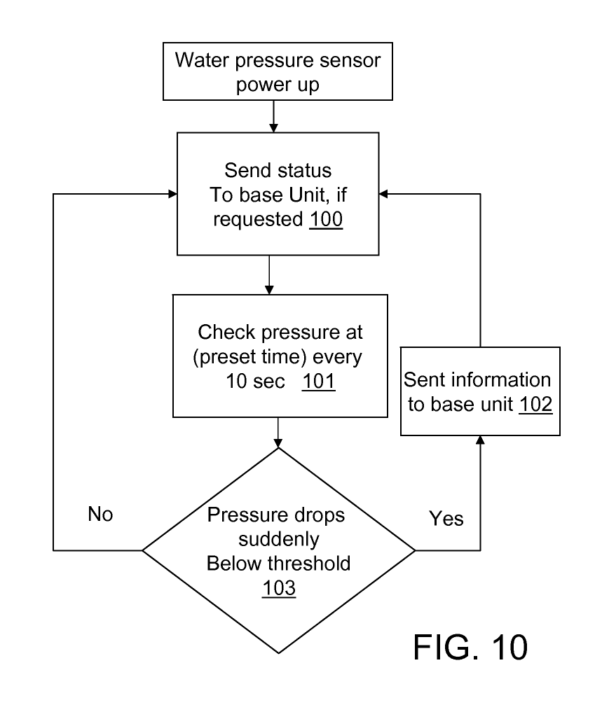

The water pressure sensor 8 is important because overpressure may damage the piping system, and appliances such as refrigerators, ice makers, and washing machines. High pressure can also damage low pressure drip irrigation often used in residential yards. The detailed operation of the pressure sensor 8 is shown in FIG. 10. Upon powering up, the sensor sends 100 its status to the base unit 1 if requested. To save power, the pressure is sampled 101 at time intervals as instructed by the base unit 1 and this information is sent 102 to the base unit 1. Optionally the pressure can be compared 103 to a preset threshold and send to the base unit 1 if it exceeds the threshold. Pressure monitoring is valuable in the detection of broken pipes in water lines, in particular in sprinkler systems.

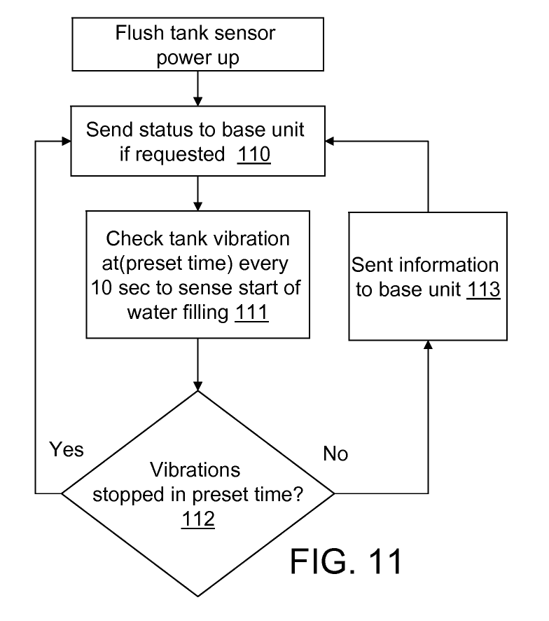

The flush tank sensor 5 can be implemented in many possible ways. For example it can sense the water lever in the tank. A preferred implementation is for this sensor to sense the vibration in the water line produced by the tank filling. The detailed operation of the flush tank sensor 5 is illustrated in FIG. 11. Upon power up, the sensor sends 110 its status to the base unit. To save power, it measures vibrations at preset time intervals as instructed by the base unit 1 to sense the onset of water filling 111. If the vibrations do not stop 112 after a preset time (for example 5 minutes) it sends 113 this information to the base unit as this situation may indicate a malfunction of the flushing system.

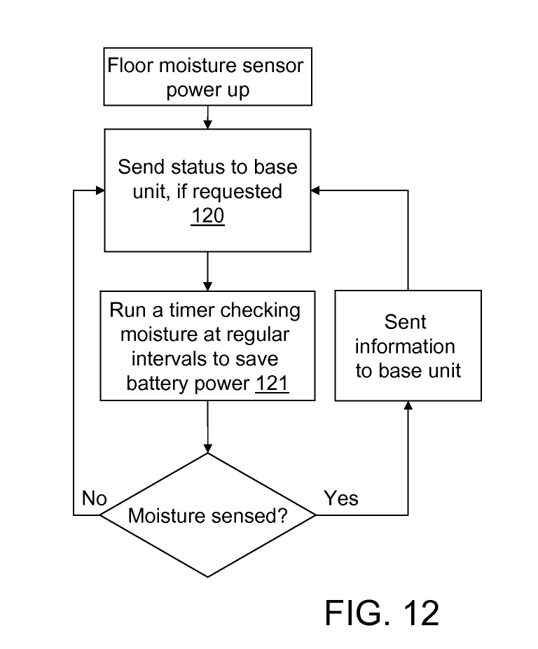

The floor moisture sensor 7 is important to detect flooding. It operation is shown in FIG. 12. Upon power up, it sends 120 its status to the base unit. To save power, it samples 121 the floor moisture at preset time intervals as instructed by the base unit 1 and sends this information to the base unit 1.

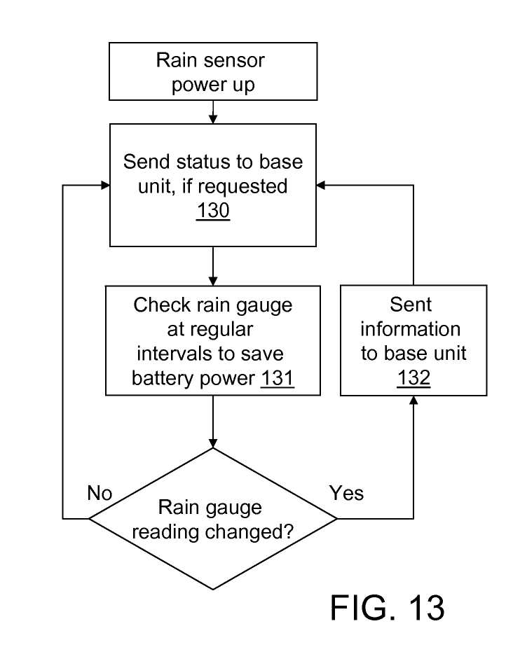

The rain sensor/gauge 16 measures rain and allows adjustment of the irrigation schedule. It operation is shown in FIG. 13. Upon power up, it sends 130 its status to the base unit. To save power, it reads 131 the gauge at preset time intervals as instructed by the base unit 1 and sends this information to the base unit 1.

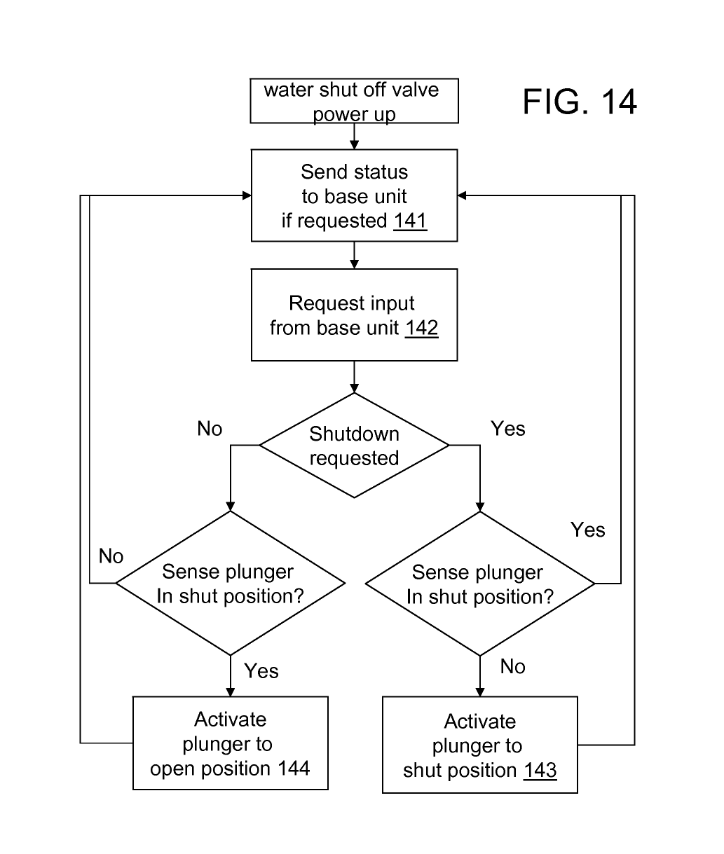

The shut off valve turns off water if one of the decision paradigms is met. For example, when excessive water usage has occurred over a given period of time. As illustrated in FIG. 14, upon power up, this actuator sends its status to the base unit. If a shut down is requested 142 and if the valve is in an open state, the actuator activates the valve to shut off 143 the water. Otherwise, if the valve is in a closed state it activates the valve to remain open 144 and maintain the water flowing.

Additional processing can be performed either at the Internet server or at the base unit. For example the energy consumed for heating water can be calculated by measuring the cold and hot water temperature and the hot water flow. This energy can be displayed in energy units (for example Watts or BTUs) or in dollars if an appropriate conversion factor is entered into the device.

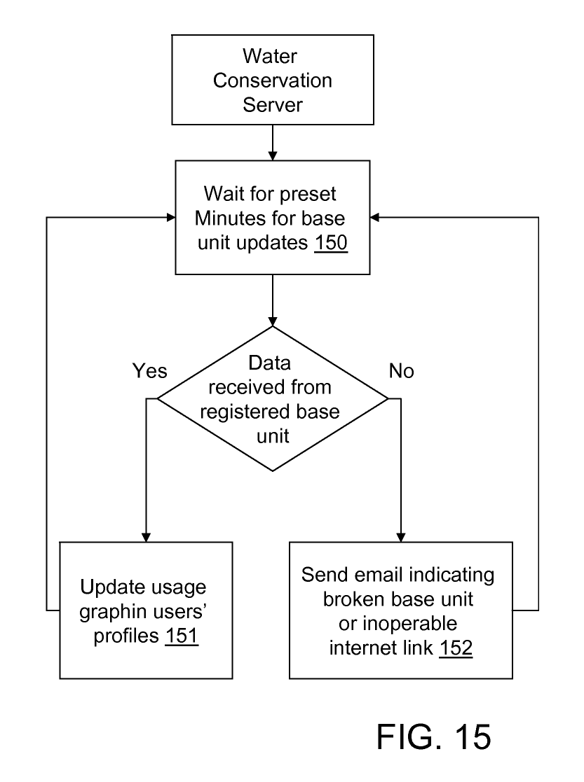

As illustrated in FIG. 1 the base unit 1 communicates with an Internet server 9. Details of this interaction are presented in FIGS. 15, 16 and 17.

FIG. 15 shows the communication between the Internet server 9 and one of the base units 1. The server waits 150 for the base unit 1 to communicate. If the server 9 receives new information, this information is incorporated into the user profile database. For example, the water usage graph could be updated 151. If the server 9 does not receive any message for a period exceeding a preset value, for example 15 minutes, an email is sent 152 to the user to notify him that the communication link with the server is inoperative or that the base unit is not functioning.

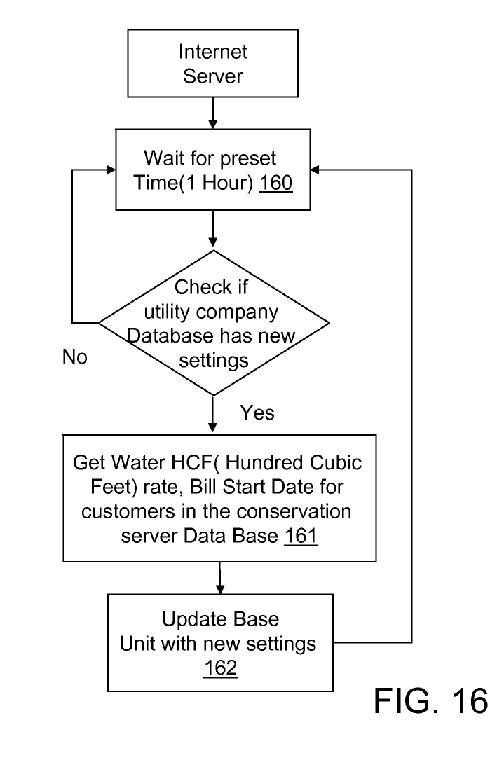

As shown in FIG. 1, the Internet server 9 also communicates with the water utility company server 14. This interaction at the Internet server 9 is illustrated in greater detail in FIG. 16. The Internet server checks 160 if the utility company has any new data affecting the utilization, availability and cost of the utility (water). The server performs this action at preset time intervals (for example one hour). In particular, it updates 161 the utility rate (typically measured in hundred cubic feet—HCF) and the bill start date.

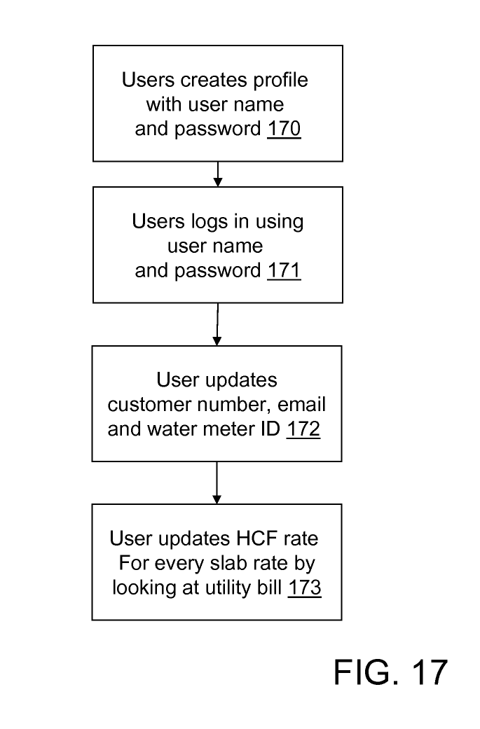

As illustrated in FIG. 17, the Internet server 9 also allows users to create 170 a profile, and to log in 171 with a user name and password. The user can enter, or update 172 his customer number, email address, and water meter ID. The user can also enter or update 173 his usage and the cost schedule used by the utility company. For example, water companies charge a lower rate for the first water quota (for example $3 for the first HCF) and then a higher rate if the user exceed that quota and even more for the next quota. These quotas of HCFs are also called first slab, second slab etc.

The base unit gets billing information from the water utility company to display water usage in dollars. Alternatively this billing information can be manually entered by the user.

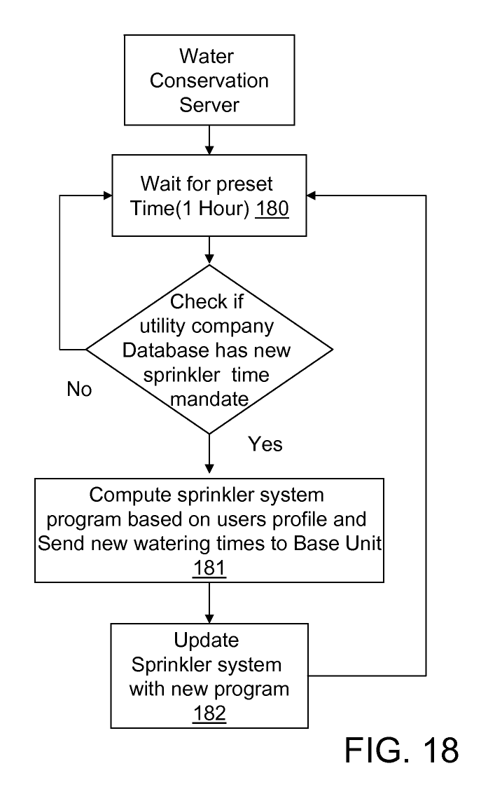

Similarly the Internet server can get mandated watering time for irrigation sprinklers from the utility company. As shown in FIG. 18, the Internet server queries 180 the utility company every preset time interval. If new data is present, it transmits 181 this information to the base unit 1 which then updates 182 its watering schedule accordingly.

As illustrated in FIG. 1, the Internet server 9 obtains weather information 15 from the national climate data center currently located at www.ncdc.noaa.gov. The server 9 can also obtain weather information from servers for the national digital forecast database XML/SOAP service currently located at www.weather.gov.gov/xml. These servers support requests from other computers and send data about a geographical area in XML format.

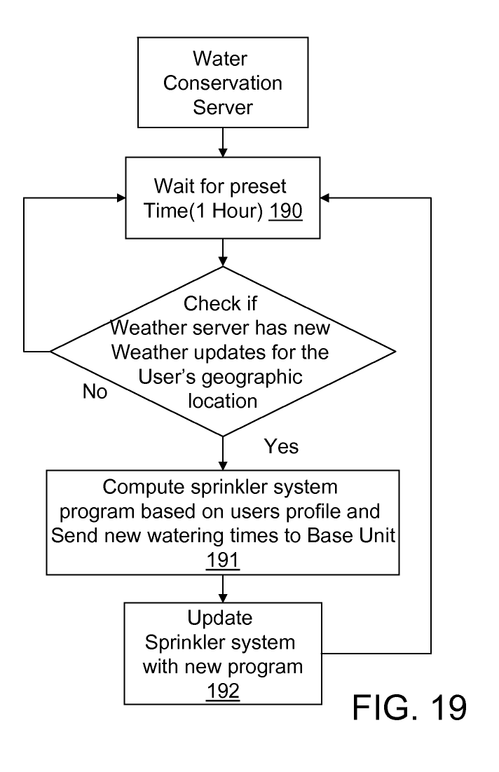

Weather information can also be used to optimize water consumption as shown in FIG. 19. The Internet server 9 requests from the public weather servers, weather data corresponding to the geographical location of each base unit. The server 9 queries 190 the weather information server every preset time interval. When it receives new information, it computes 191 a sprinkler schedule and sends this schedule to on the base unit. 1. The base unit, in turn, updates 192 the sprinkler system.

The government mandated watering schedule is also used by the server 9 to calculate watering schedules (for example weekly/daily). This schedule is then sent to the base unit 1 and used to activate the sprinklers.

The internet server can also communicate with the water company to retrieve water usage rates, discount or overcharge hours, water quality advisories.

Floor moisture sensors 6 and 7 that generate information regarding the absence or presence of a flood are also linked to the base unit 1. In the presence of a flood, an alarm is generated and an Internet message is sent to the user.

This invention can also be used to monitor water usage at different points around a house or in a residential complex, and allows the identification of problematic and wasteful water consumption behavior and usage.

Several enhancements can facilitate the incorporation of conventional water meter into this invention. The following techniques may be used.

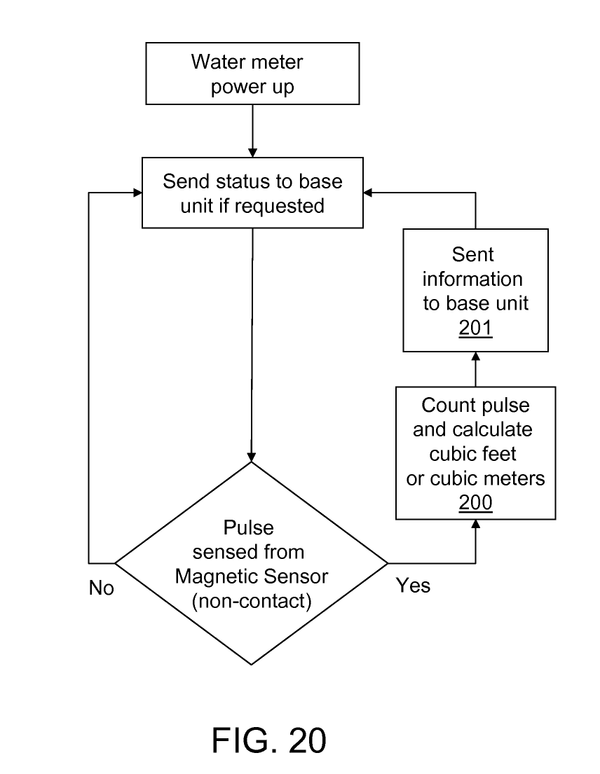

Typical water meter usually count the rotations of an impeller immersed in the water to obtain a measure of the flow. The meter senses the fluctuation of the magnetic field produced by the motion of a magnet coupled to the impeller to generate a count proportional to the water usage. This fluctuating magnetic field can be sensed outside the meter by means of a magnetic field sensor based on the Hall effect. As illustrated in FIG. 20 a magnetic sensor external to the water meter can be used to independently obtain 200 a measure of the water usage which may then be transmitted 201 to the base unit.

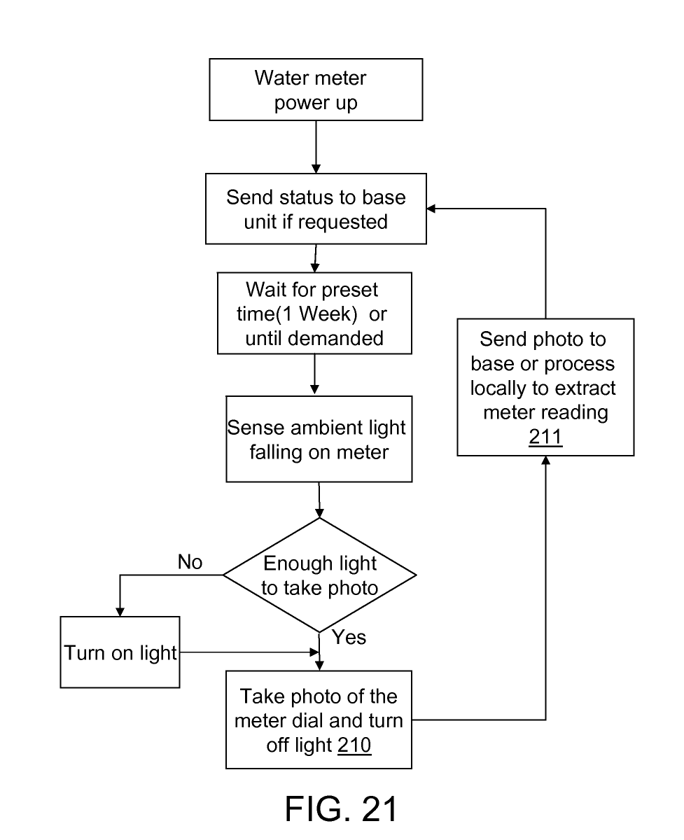

Sometimes, the magnetic field is intentionally shielded by the water meter manufacturers to prevent tempering with the meter's operation. In these cases, as shown in FIG. 21 it is possible to use an optical method to read the meter dial and to obtain a measure of water usage. For example a CCD camera can take pictures 210 of the dial and this picture can be processed to extract counter information.

It is evident to those skilled in the arts that the same technology as this invention can be used to monitor other utilities such as gas and electricity. The peripherals to monitor in these cases include watt-meters and gas meters. If solar energy is produced in the home, solar panels are peripheral that can also be included.

While the above description contains much specificity, the reader should not construe this as limitations on the scope of the invention, but merely as examples of preferred embodiments thereof. Those skilled in the art will envision many other possible variations within its scope. Accordingly, the reader is requested to determine the scope of the invention by the appended claims and their legal equivalents, and not by the examples which have been given.

I claim:

1. A water consumption monitoring and control system that allows a user to monitor and control water consumption, comprised of a base unit, said base unit comprising
a) a display and a data entry device;
b) a microprocessor functionally connected to said display and said data entry device;
c) a first communication link to at least one water meter, said first communication link functionally connected to said microprocessor, and transmitting water usage from said water meter to said base unit;
d) a second communication link to the Internet, said second communication link functionally connected to said microprocessor, and transmitting said water usage from said base unit to said user over the Internet.

2. The water consumption monitoring and control system of claim 1 wherein said microprocessor converts said water usage to monetary amounts and makes available the display of said monetary amounts to said user over the Internet.

3. The water consumption monitoring and control system of claim 1 also comprising a communication link to at least one pressure sensor, wherein said at least one pressure sensor sends water pressure information to said base unit wherein said microprocessor compares said pressure information with pre-entered criteria and generates an alarm if said pressure information does not conform with said pre-entered criteria.

4. The water consumption monitoring and control system of claim 3 wherein a message over the Internet is generated if said alarm is triggered, said message being in the form of email, tweet, or text.

5. The water consumption monitoring and control system of claim 3 also comprising a communication link to at least one water shut-off valve, wherein said at least one pressure sensor sends water pressure information to said base unit wherein said microprocessor compares said pressure information with pre-entered criteria and generates a shut-off signal if said pressure information does not conform with said pre-entered criteria, said shut off signal being sent to said at least one shut-off valve.

6. The water consumption monitoring and control system of claim 5 wherein said pre-entered criteria includes water leak and pipe breakage profiles and is used to detect said leak or said breakage.

7. The water consumption monitoring and control system of claim 5 wherein said second communication link to the Internet establishes communication between said base unit and local water utility company, said water usage and said pressure information being sent to said utility company, wherein said utility company evaluates said water usage and said pressure information against pre-set usage and pressure criteria, and sends said shut-off command signals to said base unit if said water usage and pressure information does not conform to said pre-set usage and pressure criteria, said shut off signal being forwarded to said at least one shut-off valve.

8. The water consumption monitoring and control system of claim 3 wherein said second communication link to the Internet establishes communication between said base unit and an Internet server, wherein said second communication link carries said water usage and said pressure information to said server, and wherein said server evaluates said water usage and said pressure, generates usage control information and returns usage control information to said base unit through said second communication link.

9. The water consumption monitoring and control system of claim 1 wherein said second communication link to the Internet establishes communication between said base unit and an Internet server, wherein said second communication link carries water usage information to said server, and wherein said server evaluates said water usage, generates usage control information and returns usage control information to said base unit through said communication link.

10. The water consumption monitoring and control system of claim 1, wherein said second communication link to the Internet establishes communication between said base unit and an Internet server, and furthermore wherein said Internet server receives water schedule advisories from the local government water department and generates government advisory control information, and sends said government advisory control information to said base unit.

11. The water consumption monitoring and control system of claim 1, wherein said second communication link to the Internet establishes communication between said base unit and an Internet server, and furthermore wherein said Internet server receives weather information from the weather office and generates weather advisory control information, and sends said weather advisory control information to said base unit.

12. The water consumption monitoring and control system of claim 1, also comprising a communication link to a sprinkler system, said sprinkler communication link carrying sprinkler control information to said sprinkler system.

13. The water consumption monitoring and control system of claim 1, also comprising a communication link to at least one water temperature sensor, said temperature communication link carrying temperature information from said temperature sensors to said base unit, said temperature information being used to calculate energy usage in heating up water.

14. The water consumption monitoring and control system of claim 1, also comprising a communication link to at least one vibration sensor, said vibration sensor configured to detect vibration produced by the operation of a flush toilet tank, said communication link carrying vibration data to said base unit, said vibration data being used to monitor the operation and detect malfunctions of said flush toilet tank.

15. The water consumption monitoring and control system of claim 1, also comprising a communication link to at least one floor moisture sensor, said moisture sensor link carrying floor moisture data indicative of the presence or absence of a flood, said moisture data being used to generate, if appropriate, an alarm signal and a message over the internet to said user.

16. The water consumption monitoring and control system of claim 1, comprising at least two water meters, wherein each said at least two water meters are located in different housing units.

17. A method for monitoring and controlling water consumption comprising:
a) monitoring water usage;
b) monitoring water pressure;
c) detecting breakage or leaks in water pipes by comparing, over time, said water pressure and said water usage to predetermined criteria;
d) issuing shut-off command if such said breakage or said leak is detected.

18. The method for monitoring and controlling water consumption of claim 17 also comprising issuing an internet message, said message being in the form of email, tweet or text.

19. The method for monitoring and controlling water consumption of claim 17 also comprising:
a) obtaining weather information from weather office
b) calculating watering schedule using said weather information

20. The method for monitoring and controlling water consumption of claim 17 also comprising:
a) obtaining watering advisories from local government office
b) calculating watering schedule using said watering advisories.
